(19) United States
(12) Patent Application Publication
(10) Pub. No.: US 2023/0221383 A1
(43) Pub. Date: Jul. 13, 2023

(54) Method for The Networked Monitoring of At Least One Transformer

(71) Applicants: E.ON Digital Technology GmbH, München (DE); E.ON SE, Essen (DE)

(72) Inventors: Nicholas Ord, München (DE); Philipp Bugs, München (DE); Laura Antonia Färber, München (DE); Alexander Schlüter, München (DE); Karsten Wildberger, München (DE)

(21) Appl. No.: 18/017,278

(22) PCT Filed: May 19, 2021
(86) PCT No.: PCT/EP2021/063231

§ 371 Date: Jan. 20, 2023

(30) Foreign Application Priority Data
Jul. 20, 2020 (DE) 10 2020 119 068.9

(51) Int. Cl. G01R 31/62; H01F 27/40

(52) U.S. Cl. CPC G01R 31/62; H01F 27/402

(57) ABSTRACT

The invention relates to a method for networked monitoring of at least one transformer (5), wherein the following steps/stages are performed:
receiving (110) an electromagnetic signal (210) by a monitoring component (20) at the active transformer (5), the signal (210) being specific to at least one transformer parameter of the transformer (5),
carrying out a frequency evaluation (120) based on the received signal (210) by the monitoring component (20),
outputting (130) monitoring information (240) about a result of the frequency evaluation (120) to a network (70) for transmission to a processing system (80) for evaluation (140) of the transformer parameter based on the monitoring information (240).

The present invention relates to a method for networked monitoring of at least one transformer. Furthermore, the invention relates to a monitoring component and a system for networked monitoring.

The growing world of IoT (Internet of Things) requires that “things” (i.e., objects such as doors, windows, lighting fixtures, industrial or household machines, power grids, and transformers) be equipped with physical sensors. In addition, a wired or wireless connection must be provided that connects the objects from their location to the Internet. The purpose of the networking of the objects achieved in this way is to allow the objects to work together by interacting with each other.

However, the technical effort required for integrating sensors and networking is often enormous. Especially for transformers, extensive measures are necessary. Any type of connection to a typical low-voltage transformer requires shutting down the transformer for a few hours or days in order to safely physically connect measurement cables to monitor the power or phases of the transformer. This results in interruption of service or temporary detour of power to the grid. Monitoring events such as overheating, power imbalance, line load, or oil cooling system condition may entail several days of downtime. Furthermore, costly invasive measures may be required (e.g., physically drilling into the transformer and installing expensive sensors). For these reasons, reliable, technically and economically viable networking of transformers is generally not possible. However, this also makes it difficult to flexibly manage the grid, which requires real-time monitoring of energy flows to predict supply and demand.

It is therefore an object of the present invention to at least partially eliminate the disadvantages described above. In particular, it is an object of the present invention to provide an improved solution for monitoring at least one transformer.

The foregoing object is solved by a method having the features of claim 1, by a monitoring component having the features of claim 14, and by a system having the features of claim 16. Further features and details of the invention result from the respective dependent claims, the description and the drawings. Features and details described in connection with the method according to the invention naturally also apply in connection with the monitoring component according to the invention as well as the system according to the invention, and vice versa in each case, so that reference is or can always be made mutually with respect to the disclosure concerning the individual aspects of the invention.

The object is solved in particular by a method for networked monitoring of at least one transformer, in particular power transformer and/or low-voltage transformer, preferably of a power supply network (i.e. for voltage conversion in power supply systems).

For example, a public power grid with a grid frequency of 50 Hz or 60 Hz can be provided to supply consumers with useful energy. In transformer stations, the electricity of the regional distribution network (in particular with the medium voltage of 10 kV to 36 kV) can be transformed by the transformer to supply the low-voltage end customers (in particular to the 400 V conductor voltage used in the local network). Thus, the transformer interconnects different voltage levels of the power grid. Monitoring according to the invention can be used to at least partially determine an electrical load on the power grid and/or the transformer. Furthermore, the method according to the invention may also provide at least two or at least three or at least four or at least 10 or at least 100 or at least 1000 or at least 10000 transformers, which are monitored simultaneously by the method. In this case, the individual steps/stages of the method according to the invention can each be carried out in parallel for the transformers. Since the transformers are networked, a common processing system can be provided at least in part for the transformers.

In particular, it is intended that the following steps/stages are carried out, preferably one after the other in the specified order, whereby individual and/or all of the steps/stages can also be carried out repeatedly if necessary:
receiving, preferably contactless and/or wireless receiving, an electromagnetic signal by a monitoring component at at least or exactly one active transformer (i.e. in particular without interruption of operation of the transformer), in particular power transformer and/or low-voltage transformer, preferably the signal being specific for at least one transformer parameter of the transformer,
carrying out a frequency evaluation, in particular a digital Fourier transform, based on the received signal by the monitoring component,
outputting monitoring information about a result of the frequency evaluation (i.e., for example, a spectrum) to at least one network for transmission (of the monitoring information) to a processing system (such as a cloud) for evaluation, i.e., for example, for value determination, of the transformer parameter based on the monitoring information.

In other words, the processing system serves to evaluate the transformer parameter in order to provide monitoring through this evaluation. The processing system can be designed/configured as a central processing system in order to receive monitoring information from different and spatially remote monitoring components and to use this information to evaluate the transformer parameters of different transformers. It is also possible that several transformer parameters of different transformers can be evaluated on the basis of one monitoring information.

It is also advantageous if the monitoring component has a receiving component for receiving the electromagnetic signal. The receiving component may comprise at least one receiving antenna and/or at least one coil. Furthermore, the receiving component may be adapted to receive the signal as a low frequency signal, in particular in the range of 40 Hz to 70 Hz, e.g. substantially 50 Hz or 60 Hz.

Furthermore, it can be intended that the monitoring component, in particular the receiving component, and the at least one transformer are arranged at a distance from each other. The monitoring component and/or the receiving component can be designed/configured accordingly to receive the signal and carry out the frequency evaluation at a distance (e.g., at least one meter away) from the transformer. Furthermore, the distance, in particular as a minimum distance, may also be in the range of 0.5 meters to 3 meters, preferably 1 meter to 2 meters. The amplitude of the received signal may depend on this distance, i.e. the distance between the transformer and the monitoring component. On the basis of the amplitude, it may therefore also be possible to distinguish between different transformers. When mounting the monitoring component, this distance can be measured and/or maintained, if necessary. In contrast to conventional methods, a large amplitude of the signal can enable an exact determination of the transformer parameter without having to consider the risk of a high current.

Furthermore, the monitoring component may also be designed/configured as a mounting component. For example, mounting the monitoring component may include mounting the monitoring component to a wall or roof of a transformer station. Further, the monitoring component may include a housing with mounting means/elements to perform such mounting. Further, the monitoring component may be subsequently mounted after the transformer has already been fully mounted. It may also be possible for the mounting to be performed without interfering with the transformer. The distance between the transformer and the monitoring component can further simplify the assembly.

The monitoring information is transmitted via at least one network so that the monitoring can be networked. Specifically, this can mean that several monitoring components are connected to the network, each of which outputs monitoring information for at least one or more transformers to the network. The monitoring components may monitor different transformers, if applicable. Also, each of the monitoring components may monitor a plurality of different transformers, respectively, and thus receive a signal that may have been generated by one or more of those transformers. The monitoring can be non-invasive to the transformer by receiving the signal wirelessly or without contact with respect to the transformer. This allows reliable monitoring of a single transformer as well as monitoring of an entire power grid in a technically simplified manner and during operation of the transformer.

If a monitoring component monitors several transformers, it is optionally possible to distinguish from which transformer the signal originates on the basis of the monitoring information, e.g. on the basis of the magnitude of frequency signatures of the monitoring information. For example, a transformer station may have several transformers (of equal priority for monitoring) (e.g. for voltages of 10 kV or 20 kV). The transformer does not need to be adapted or contacted in order to be able to evaluate and/or measure the energy transformed by the transformer according to a method according to the invention or with a monitoring component according to the invention. In particular on the basis of the distance and/or due to a maintenance of a constant distance to the transformers, the transformer parameters of the different transformers can be distinguished in the signal. The transformer parameter for each of the transformers can then be determined in real time.

The transformer can be designed/configured as a low-voltage transformer, i.e. for transforming voltages in the range of 10 kV or 20 kV, especially in distribution nodes (which are the last mile of power to all houses, buildings and factories).

The at least one transformer parameter may comprise an electric current and/or a load and/or an electric power and/or the phases of the transformer and/or the like. Thus, the transformer parameter may be specific to the load and/or operation and/or condition of the transformer. Thus, the monitoring may be directly implemented as a measurement of the transformer parameter or as a determination of the state of the transformer, in particular the load, by evaluating the transformer parameter. The condition includes, for example, an overheating and/or a power imbalance and/or a line load and/or a condition of the oil cooling systems of the transformer and/or the like. The state of the transformer can thus be determined by evaluating the transformer parameter.

In particular, the invention is based on the realization that the result of the frequency evaluation is specific to the transformer parameter and thus can also be specific to the state of the transformer. The use of the result of the frequency evaluation by the processing system further makes it possible to perform monitoring in a technically simple manner with little computational effort.

It is also possible for the frequency evaluation to be implemented as a Fourier transform, in particular a Fast Fourier transform (FFT). The Fourier transform can be used to decompose the received signal into its frequency components, i.e. in other words to determine a spectrum. This makes it possible to evaluate the transformer parameter on the basis of the frequency components. The result of the frequency evaluation can thus be a spectrum whose values are digitally represented by the monitoring information.

A further advantage can be that the monitoring component is structurally separate from the transformer and/or the processing system. Due to the separate design/configuration from the transformer, the monitoring component can thus be used for monitoring even during operation of the transformer and without structural adaptation to the transformer for mounting the monitoring component. The separate design/configuration to the processing system makes it possible to use a central processing system, which can be connected to several monitoring components via the at least one network. The central processing system can thus evaluate and, in particular, determine the transformer parameter for different transformers.

According to a further advantage, it can be provided that the signal in the form of an electromagnetic field and/or electromagnetic waves is generated by the (at least one) transformer during operation (i.e. in an operationally active state), with the monitoring component preferably being arranged spatially on the transformer and/or at a distance from the transformer within reception range of the signal. Accordingly, the signal can be implemented as a signal which is generated by only one transformer, or can also be implemented as a superposition of the fields or waves which are generated by several transformers. The distance of the monitoring component from the transformer can be, for example, at least one meter or at least two meters or at most two to three meters.

Furthermore, it is optionally possible within the scope of the invention that the signal is implemented as a low frequency signal, in particular in the frequency range from 40 Hz to 70 Hz and/or with a frequency of substantially 50 Hz or 60 Hz. In this case, the frequency of the signal may correspond to the network frequency of the network in which the transformer is used.

It may be further possible that the following steps/stages are carried out to evaluate and, in particular, determine the at least one transformer parameter:
receiving the output monitoring information by the processing system, preferably through an electronic network interface of the processing system,
performing a process (preferably by the processing system), in particular evaluation, of the received monitoring information, preferably by an evaluation means/element (in particular of the processing system), in particular in order to use a result of the processing as information about the transformer parameter.

The processing can be performed, for example, by statistical algorithms and/or by a detection of peaks and/or maxima in the monitoring information. Also, centroid averaging and/or pattern recognition or the like may be performed on the monitoring information for processing. Accordingly, the evaluation means/elements may be designed/configured as a computer program or the like to perform said process. The information about the transformer parameter is implemented, for example, as a value-based determination of the transformer parameter, e.g. of an electrical output current of the transformer, or as an assignment to a state of the transformer.

The monitoring information is implemented, for example, as a spectrum of the signal, which is the result of the frequency evaluation. Exceeding predefined threshold values of the amplitudes of certain frequency components and/or a certain frequency pattern can provide conclusions about the transformer parameter. Accordingly, to a further possibility, a possibly empirically determined assignment of certain predefined spectra to certain transformer parameters or states can also be provided. Based on this assignment, the spectrum of the monitoring information can then be assigned to the corresponding transformer parameter or state, and thus the monitoring can be performed in a simple manner. The assigned transformer parameter or state is then the result of the evaluation. If the assignment is made to a critical transformer parameter or state, which indicates, for example, an overload of the transformer, a warning message can be issued to a user if necessary. The evaluation means/elements includes, for example, a predefined table for this assignment.

In a further possibility, it can be provided that the evaluation means/elements has at least one artificial neural network to perform the process, in particular evaluation, according to machine learning on the basis of a learned information of the evaluation means/elements. A neural network makes it possible, instead of an empirical manual assignment of the monitoring information to a transformer parameter or state, to obtain this assignment automatically by training. For this purpose, training data can be used, for example, in the form that input data comprise predetermined monitoring information which is assigned to predefined transformer parameters or states of the transformer as ground truth. Through training, the learned information can be obtained, for example, in the form of neuron weighting of the neural network.

Optionally, it is conceivable that the transformer parameter is implemented as an electrical parameter, preferably electrical current, of the transformer in order to perform the process, in particular evaluation, of the received monitoring information by the evaluation means/elements for current measurement at the transformer and/or for detecting a load profile (also: load shape or load curve) of the transformer. In this case, a kilowatt-precise measurement does not necessarily have to be carried out at the transformer, but rather, according to the invention, a determination of the transformer parameter can be carried out in real time without contact. For this purpose, if necessary, several pieces of monitoring information can also be temporarily stored or stored in non-volatile memory in order to carry out the evaluation and/or detect the load profile. The load profile can comprise the temporal course of the power consumed by the transformer over a predefined temporal period.

The transformer parameter may be specific to a load on the grid and/or the power system. In particular, the load may be a function of three parameters in the power grid and may result from, for example: more consumption by factories, homes or offices near that one transformer, the ability of wind or solar power to deliver power to those customers immediately and at the same time to the same grid—this will then show up as reduced load, and reduced consumption with over renewable generation—in which case two transformers in local grids will be out of balance.

In a further possibility, it may be provided that the following steps/stages are performed, in particular before and/or during and/or after the output:
detecting a time information about a time of receiving the signal by the monitoring component,
associating the time information to the monitoring information to output the monitoring information with the associated time information,
performing the process, in particular evaluation, of the received monitoring information by the evaluation means/elements and/or the processing system on the basis of the time information, the received monitoring information preferably being sorted in time on the basis of the associated time information.

The time information is, for example, in the form of a time stamp for the monitoring information. It may be an objective to generate the monitoring information in the form of “database-ready” structured data with ordered time stamps for large data sets. The monitoring component may have at least one evaluation component comprising at least one DPU (data processing unit). The data from the evaluation component may have accurate data stamps, but may not arrive at the processing system in a time-ordered sequence, since, for example, millions of pieces of data may arrive from thousands of DPUs across multiple networks, each with its own latencies—a timestamp may arrive fractions of a second later, even though the event itself occurred earlier in real time. The advantage is that this “unstructured data” is technically far easier to operate than the classic database-structured data, where everything is time-ordered (but technically complex).

By using the time information, it is also possible that during the processing, in particular evaluation, of the received monitoring information by the evaluation means/elements and/or the processing system, several monitoring information items following each other in time can be processed. For example, a temporal progression and in particular a temporal pattern can be evaluated for this monitoring information in order to detect an anomaly that indicates a critical state of the transformer.

A further advantage can be achieved within the scope of the invention if the frequency evaluation is carried out for frequencies at least in the range from 10 Hz to 100 Hz, preferably in the range from 40 Hz to 70 Hz, preferably in order to carry out the evaluation of the transformer parameter also on the basis of specific frequency components in this range. Thereby, the frequencies used for the frequency evaluation can correlate with the network frequency of the power system in which the transformer is used. In particular, the frequency evaluation for frequencies above 1 kHz or above 100 Hz can be omitted.

Furthermore, it is conceivable that the amplitudes in the signal are specific to the amount of energy or load curve transformed by the transformer. A frequency deviation in the signal can be specific for a “state of health”, i.e. also a defect of the transformer, and thus be detected by the frequency evaluation. The frequency evaluation can be carried out, for example, with an accuracy of 0.01 to 0.04, preferably substantially 0.02 Hz. The accuracy may depend on a time component of the monitoring component. To achieve a high accuracy in the frequency evaluation, the monitoring component or the time component can have a TXCO (engl. Temperature Compensated Crystal Oscillator), which can be suitable to compensate temperature deviations and provide a constant frequency. For example, a coupling of the TXCO with a central clock of the monitoring component or the time component can be used to synchronize the monitoring information and/or to determine the time information and/or for frequency evaluation.

It is possible that for the frequency evaluation at least one time information is determined by a time component. The time component comprises, for example, an oscillator such as a TXCO for providing this time information. It may be possible that the time component determines the accuracy and/or resolution in the frequency evaluation. For example, deviation from the network frequency (e.g. 50 Hz) can be determined with it. For example, an accuracy in the range of 0.001 to 0.1 Hz, preferably 0.01 to 0.03 Hz can be provided here. In this way, frequency deviations in the signal can be determined particularly reliably by means of the frequency evaluation. In order that deviations can also be reliably determined at a fine granular level and in real time, the oscillator can, if necessary, be used for repeated provision of the time information. If necessary, this provision can be repeatedly and regularly synchronized with a central clock. For example, the time information includes information about a current time. This information can be regularly synchronized with the central clock, e.g. via NTP (Network Time Protocol), and generated between synchronizations via the oscillator.

It is conceivable that the monitoring component comprises a time component in order to provide time information (e.g., about a time interval) for the frequency evaluation and/or about a time of reception of the signal by the monitoring component. The time information can thus be used, for example, for frequency evaluation and/or for providing a time stamp for evaluation at the processing system. It is possible that a time of the reception of the signal and/or the frequency evaluation and/or the determination of the result of the frequency evaluation is associated with the time information. The time component may have a central clock and/or a TXCO for providing the time information in order to perform this linkage with high temporal accuracy and/or high temporal resolution. For example, an accuracy in the range of 0.001 to 0.1 Hz, preferably 0.01 to 0.03 Hz, may be provided here. In other words, a highly granular real-time determination of the transformer parameter can be performed. After synchronization of the time component by the central clock (e.g. via NTP), the TXCO can then provide the time information with the high accuracy.

It may be further possible that at least carrying out the frequency evaluation and/or the transformer parameter evaluation is carried out in real time. As the power grid itself becomes more volatile, with more and more renewable energy sources such as wind and solar causing unpredictable instability (many megawatts can fluctuate with wind or solar as well as clouds), real-time monitoring can be very beneficial in solving the associated problems. In this way, the networking of transformers and, in particular, low-voltage transformers made possible by the invention can be a particularly viable technical solution for flexible management of the power grid.

According to an advantageous further development of the invention, it may be provided that a state of the transformer is monitored by the method according to the invention during operation. The transformer is thus actively used for voltage transformation while the monitoring is carried out. This can provide a clear advantage over invasive monitoring methods, in which the transformer must be switched off at least temporarily.

Furthermore, it is conceivable that the (at least one) network is at least partially implemented as the Internet, i.e. comprises the Internet. Also, the network may comprise a mobile network or at least one local area network (e.g., a LAN, i.e., a Local Area Network). A plurality of different monitoring components may be in data communication with a (single) processing system via the at least one network to perform monitoring for the respective transformers.

Also an object of the invention is a monitoring component for networked monitoring of at least one transformer, comprising:
a receiving component for receiving an electromagnetic signal at an active transformer, preferably the signal being specific to at least one transformer parameter of the transformer, an evaluation component for carrying out a frequency evaluation based on the received signal,
an output component for outputting monitoring information about a result of the frequency evaluation carried out to at least one network for transmission to a processing system, in particular a central processing system, for evaluation and, in particular, value determination of the transformer parameter on the basis of the monitoring information.

Thus, the monitoring component according to the invention provides the same advantages as have been described in detail with reference to a method according to the invention. In addition, the monitoring component may be suitable for carrying out a method according to the invention.

It is also advantageous if the receiving component has a receiving antenna which is designed/configured to receive the signal as a low frequency signal, in particular in the range from 40 Hz to 70 Hz. Alternatively or additionally, the evaluation component may comprise at least one data processing unit to carry out a frequency evaluation in the form of digital data processing. The output component may in particular be designed/configured as a network interface and/or as a wireless (i.e. radio) interface. The receiving component and/or the evaluation component may be arranged in a common housing and, in particular, form a common component.

Also an object of the invention is a system for networked monitoring of at least one transformer, comprising:
a monitoring component according to the invention,
a processing system for evaluating the transformer parameter based on the monitoring information.

Thus, the system according to the invention brings the same advantages as have been described in detail with reference to a method according to the invention and/or a monitoring component according to the invention.

Advantageously, the method according to the invention and/or the monitoring component according to the invention can enable the detection of multiple (IoT) physical events at multiple locations simultaneously without requiring physical contact with the object. Accordingly, the monitoring component and the transformer may be physically spaced apart and/or arranged for monitoring.

It is possible that at least one further detection parameter is detected in addition to the signal when receiving. The at least one further detection parameter may include, for example, at least one of the following: Vibration, audio noise, humidity, light, infrared, CO₂ (carbon dioxide), volatile organic compounds (VOCs) or total volatile organic compounds (TVOCs). Detection can also be performed, for example, by the receiving component, but possibly also with other environmental sensors. It is possible that the monitoring component has at least one sensor to detect the detection parameter. The monitoring information can be formed from the at least one sensed detection parameter, so that the monitoring information is information about this detection parameter (e.g., represents this detection parameter in terms of values). For example, in the case of detecting an audio sound as a detection parameter, the monitoring information may comprise a value-based audio recording of the audio sound.

The monitoring component may include at least one of the following sensors to detect the detection parameter:
an audio sensor to detect an airborne sound as a detection parameter, wherein preferably the detection parameter detected by the audio sensor can be specific for an on or off switching of mechanical circuit breakers at the transformer, so that preferably on the basis of the monitoring information the state of the transformer can be determined in the form of a partial discharge of the transformer,
a light sensor, wherein light can be specific as a detection parameter for an opening of a door at the transformer house and/or for a time of day, so that preferably the opening of the door as an event or the time of day can be determined on the basis of the monitoring information,
an infrared sensor to detect heating as a detection parameter, so that a temperature at the transformer can preferably be determined based on the monitoring information,
a CO₂ sensor, in particular to determine a presence of people based on the monitoring information,
a TVOC sensor, in particular to determine an oil leak based on the monitoring information,
a pressure sensor, in particular to perform a weather forecast based on the monitoring information and possibly in combination with the use of a humidity sensor and/or temperature sensor.

In addition, the monitoring component according to the invention may have a time component such as a central clock to determine the time information for received signals. The time it takes for such complex information as the monitoring information to get from the monitoring component to the network and be processed in real time may be very long or require a lot of data bandwidth, especially in areas where connectivity is poor. Similarly, such data may need to be synchronized—for example, a single burst of vibration in the spectrum of the monitoring information may be meaningless if it cannot be correctly time-mapped. This may require an atomically accurate central clock with which to synchronize all devices, the cloud, and the individual data. The central clock may be used, for example, to synchronize the monitoring information and/or to determine the time information.

Since the acquisition rate for a short event such as a change in energy or a small change in vibration or tone in a transformer may be less than a second—but in that second there are 2000 or more combined frequencies, each with its own magnitude, that identify that event like a “digital fingerprint”—it may be envisaged to process this via a standard Fast Fourier transform for each event in parallel and locally synchronized to the same UTC (coordinated universal time).

To determine the time information, a UTC can be determined. This can be done by synchronization using a time component, e.g. by using the “Network Time Protocol” (NTP). The time component or the DPUs can fetch the current time (UTC) from a source (such as a time server) in the NTP network. Furthermore, this current time can be resynchronized regularly, e.g. hourly, via NTP. The monitoring component or the time component can also have its own timer, which however has a lower accuracy than the source in the network. However, by means of a TXCO, this accuracy can be improved and/or approximately maintained between synchronizations. Further, it may be possible for the processing system to be synchronized to the same source.

It may be provided for installation that the raw monitoring information is first displayed to an installer so that the installer can see in real time how the monitoring component, and in particular the receiving component, is positioned and calibrated in the field. Positioning and placement can be critical to obtaining clear and reliable data from the receiving component (i.e., a physical sensor).

Further advantages, features and details of the invention will be apparent from the following description, in which embodiments of the invention are described in detail with reference to the drawings. In this connection, the features mentioned in the claims and in the description may each be essential to the invention individually or in any combination. The figures are showing:

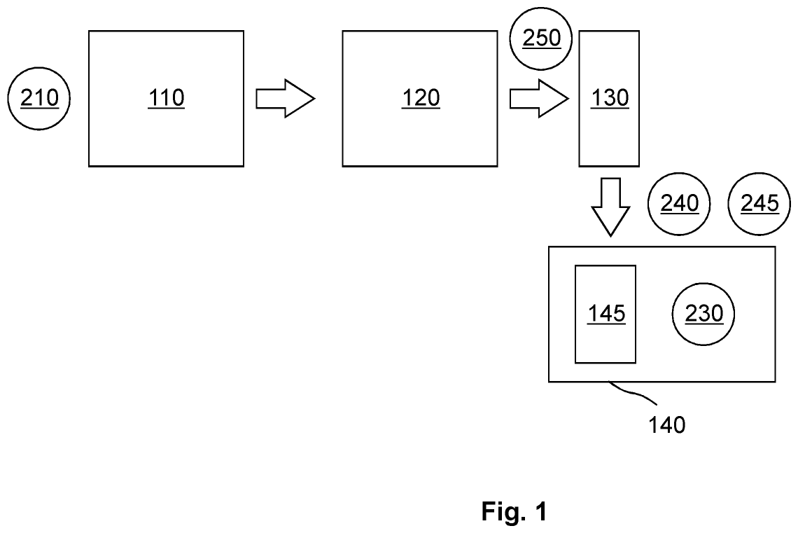

FIG. 1a a schematic diagram for visualizing process steps/stages,

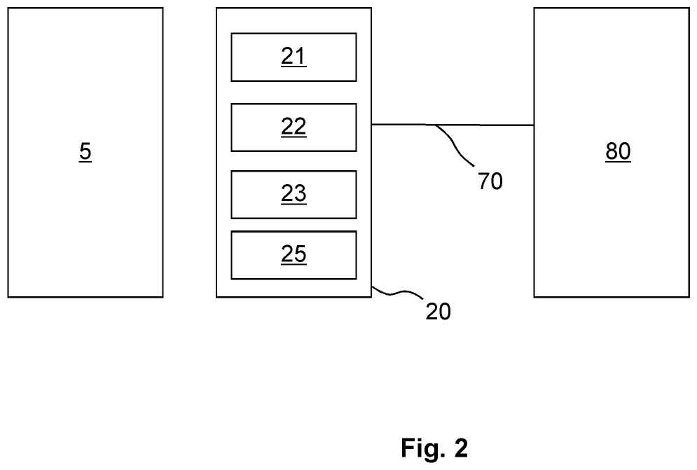

FIG. 2a schematic representation of parts of a system according to the invention and a monitoring component according to the invention,

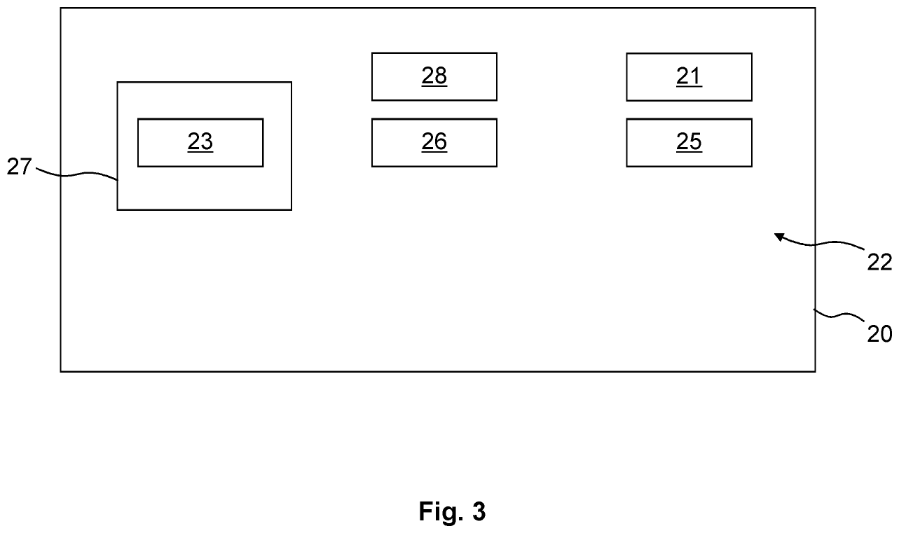

FIG. 3a schematic representation of parts of a monitoring component according to the invention.

In the following figures, the identical reference signs are used for the same technical features even of different embodiment.

FIG. 1 schematically visualizes a method according to the invention for networked monitoring of at least one transformer 5. According to a first process step/stage, an electromagnetic signal 210 is received 110 by a monitoring component 20 at a transformer 5. The transformer 5 can be active during the receiving 110 and thus generate the signal 210, for example, during operation. Accordingly, the signal 210 is specific to at least one transformer parameter of the transformer 5. Subsequently, according to a second method step/stage, a frequency evaluation 120 can be carried out by the monitoring component 20 on the basis of the received signal 210. Specifically, a Fast Fourier transform may be used for this purpose so that the frequency evaluation 120 can be carried out by the monitoring component 20 even with low computing power. For example, the monitoring component 20 comprises at least one microcontroller to carry out the frequency evaluation 120. Subsequently, monitoring information 240 about a result of the frequency evaluation 120 may be output to a network 70 at step/stage 130 to transmit the monitoring information 240 to a processing system 80. The processing system 80 may be for evaluating 140 the transformer parameter based on the monitoring information 240.

Advantageously, this invention can provide full real-time visibility of the transformer 5 power system at exceptionally low equipment and data processing costs.

Further, the following steps/stages may be performed to carry out the evaluation 140 of the at least one transformer parameter. According to a first step/stage in the evaluation 140, the output monitoring information 240 may be received by the processing system 80. According to a second step/stage in the evaluation 140, a processing 145 of the received monitoring information 240 may be performed by an evaluation means/elements 230 to use a result of the processing 145 as information about the transformer parameter.

Further, it is possible that a time information 245 about a time of receiving 110 the signal 210 by the monitoring component 20 is acquired. This time information 245 may be associated with the monitoring information 240 to output the monitoring information 240 with the associated time information 245 at step/stage 130. Processing 145 may then be performed based on the time information 245, preferably time sorting the received monitoring information 240 based on the associated time information 245.

It is also conceivable that the frequency evaluation 120 is implemented as a Fourier transform 120, in particular a fast Fourier transform 120 (FFT), by means of which the received signal 210 is decomposed into its frequency components 250 in order to carry out the evaluation 140 of the transformer parameter on the basis of the frequency components 250

FIG. 2 schematically shows parts of a monitoring component 20 according to the invention for networked monitoring of at least one transformer 5. A receiving component 21 can be used to receive 110 the electromagnetic signal 210 at the active transformer 5, the signal 210 being specific to at least one transformer parameter of the transformer 5. The receiving component 21 may comprise or be configured as a receiving antenna 21 to receive the signal 210 as a low frequency signal 210, in particular in the range of 40 Hz to 70 Hz. Further, an evaluation component 22 may be provided for carrying out a frequency evaluation 120 based on the received signal 210. An output component 23 may enable output 130 of monitoring information 240 on a result of the frequency evaluation 120 to a network 70 to perform transmission of the monitoring information 240 to a processing system 80.

Also shown schematically in FIG. 2 is a system according to the invention for networked monitoring of at least one transformer 5, comprising a monitoring component 20 according to the invention and a processing system 80 for evaluating 140 the transformer parameter on the basis of the monitoring information 240. The processing system 80 comprises, for example, at least one server to form a cloud for processing 145. Accordingly, the network 70 may be implemented at least in part as the Internet.

FIG. 3 shows a monitoring component 20 with further details. The monitoring component 20 and/or the at least one evaluation component 22 or DPU 22 of the monitoring component 20 can each have at least four main sections. In a first main section, a group of one to ten sensors 25 and/or the receiving component 21 and/or the associated interfaces may be provided. In a second main section, a data processing section 26 may carry out frequency evaluation 120 and/or further processing 145. For this purpose, the data processing section 26 may comprise at least one microcontroller and/or integrated circuit. Further, a communication section 27 may be provided as a third main section. The communication section 27 may optionally include a wireless local area network (WLAN) interface and/or a long term evolution (LTE) interface as a data interface to the network 70. The uplink bandwidth for output to the network 70 may be, for example, 150 kbps. The communication section 27 may have the output component 23, which may have a radio interface, in particular a 2.4 GHz radio interface, with a corresponding antenna for output. A fourth main section is formed, for example, by a central clock system 28 that synchronizes the data from the sensors 25 (also with other DPUs) by connecting it to a common atomic clock reference, with which the cloud may also be synchronized. The main sections may be mounted on a common PCB, allowing the monitoring component 20 to form a compact component. In this way, the monitoring component 20 can also be designed/configured to be movable independently of the transformer 5 and, in particular, to be portable by a person. The clock system 28 may have at least one time component such as an oscillator and/or an NTP interface.

It is possible that the sensors 25 are connected to the data processing section 26 or the microcontroller, for example, via standard I²C digital interfaces or via analog-to-digital converters or digital audio interfaces. The sensors 25 are configured, for example, to detect at least one of the following sensing parameters: Gas, pressure, light, humidity, temperature, heat (thermal image), vibration (accelerometer), pyroelectric infrared direction detection, electromagnetic interference (EMI), and sound (audio).

The acquired signal 210 and/or the other acquired acquisition parameters of EMI and/or audio and/or vibration can be further processed in parallel on the evaluation component 22 and in particular the microcontroller with the FFTs (Fast Fourier Transforms) at the same time, if necessary, to achieve an optimal data output of, for example, 1.3 kb per second. This is a very dense data rate that allows accurate frequency and magnitude data of local events to be transmitted to the processing system in real time.

It has been found that it is advantageous if the frequency evaluation 120 is carried out at the local chip level, i.e. by the evaluation component 22, and thus by the monitoring component 20 locally at the transformer 5 and not remotely therefrom by the processing system 80.

The at least one other sensor 25 may comprise an EMI sensor that detects a resonant frequency at 50 Hz or 60 Hz. This critical measurement can be calibrated accurately to the energy flowing through the transformer 5. The distance to the transformer 5 can be taken into account. Of particular note here is that no part of the monitoring component 20 needs to be physically connected to the transformer 5.

The reliability of the monitoring and, in particular, the evaluation 140 of the transformer parameter based on the monitoring information 240 can be further improved and supported if further detection parameters are detected by further sensors 25. The monitoring information 240 may then comprise at least one piece of information about these sensed sensing parameters. This information may also be evaluated by the processing system 80 and, if necessary, compared to the transformer parameter to determine a condition of the transformer 5. In addition to using EMI and audio as possible detection parameters (a transformer 5 makes a low frequency “humming” noise), the use of a vibration in the environment of the transformer 5 may optionally be considered. Mechanical vibrations, which travel slower through surfaces than electromagnetic waves or audio noise through the air, can then be detected as a detection parameter. Since humidity and temperature may also correlate with the condition of transformer 5 and the transformer parameter, respectively, it may also be possible to capture these sensing parameters. These then correlate to form complex data that is precisely synchronous with time and can accurately describe the energy load (EMI) that correlates with the condition of transformer 5.

When a partial discharge or internal arc occurs in a transformer 5 (i.e., a PD event occurs), both the vibrations, the sounds, and the electromagnetic fields change rapidly. This is usually difficult to detect, and there is no known single “sensor” for partial discharge (PD). In contrast, monitoring information 240, especially if it has additional information not only about the result of frequency evaluation 120 but also about the sensed sensing parameters, can be used to detect such an anomaly. For example, a time history of the monitoring information 240 can also be evaluated for this purpose. If a transformer 5 experiences more than 3 PD events, it is statistically likely to fail. Therefore, a warning message may be outputted when this condition is detected by the evaluation 140.

Advantageously, machine learning can be used to associate the corresponding monitoring information 240 with a state of the transformer 5. Thus, these anomalies can be detected like TE.

Further, when the transformer 5 is overloaded, a loud characteristic noise and vibration may occur, which the monitoring component 20 can accurately detect and monitor the processing system 80.

In addition, for monitoring purposes, the evaluation 140 can be used to locate power transients. Usually, there are at least two low-voltage transformers 5 in each local network in order to be resilient in case of a failure.

Furthermore, the monitoring component 20 can advantageously measure the actual load of each transformer 5 inductively via EMI, i.e. via the corresponding EMI sensor. Based on the load level, the power demand and power supply (e.g., from distributed generation facilities in industrial areas) in the area of the transformer 5 can be derived in real time. That is, it can be measured whether the actual load on the grid is likely to exceed the physical capacity of the grid. Thus, it provides information about the remaining degree of flexibility in the grid. This remaining degree of flexibility can be calculated as the difference between the actual load and the network capacity. Thus, the monitoring according to the invention facilitates the calculation of the actual degree of flexibility in the network in real time. It may also be possible to use the monitoring to determine the degree of utilization of the network and to derive the degree of flexibility from this value.

It may be possible for the monitoring component 20, which may be local to the location of the transformer 5 with respect to the transformer 5, to process the data (such as EMI, audio, and vibration) received by the sensors 25 at least partially using a frequency evaluation 120 locally to increase data accuracy. The frequency evaluations 120, if processed correctly over, for example, an hour, may yield a fully accurate calibration of the actual output of the transformer 5 as if measured by a physically connected meter that is still 1 meter or more away.

In addition, the sensors 25 may also detect temperature and humidity data that changes as production and demand patterns change. Accordingly, the monitoring information 240 may be formed from the signal 210 and the other sensing parameters, and thus may include information about the temperature and humidity at the location of the transformer 5. This combination of data enables, for example, further predictions regarding the future load on the power grid or congestion in the grid.

The monitoring component 20, and in particular the evaluation component 22, may also enable planning of predictive maintenance by evaluating the monitoring information 240.

Based on the frequency evaluation 120 and/or the evaluation 140 and/or processing 145, a current load of the transformer 5 can optionally be detected and a warning can be issued immediately if the safe rated power of the transformer 5 is detected to be exceeded.

The foregoing explanation of the embodiments describes the present invention exclusively in the context of examples. Of course, individual features of the embodiments may be freely combined with one another, provided that this is technically expedient, without departing from the scope of the present invention.

### LIST OF REFERENCE SIGNS

5 Transformer
20 Monitoring component
21 Receiving component
22 Evaluation component
23 Output component
25 Other sensors
26 Data processing section
27 Communication section
28 Time component, clock system
70 Network
80 Processing system
110 Receive
120 Frequency evaluation, Fourier transform
130 Output
140 Evaluation
145 Processing
210 Signal, low frequency signal
230 Evaluation means/elements
240 Monitoring information
245 Time information
250 Frequency components, spectrum

1. A method for networked monitoring of at least one transformer, wherein the following is performed:
receiving an electromagnetic signal by a monitoring component at the active transformer, the signal being specific to at least one transformer parameter of the transformer,
carrying out a frequency evaluation based on the received signal by the monitoring component,
outputting monitoring information about a result of the frequency evaluation to a network for transmission to a processing system for evaluating the transformer parameter based on the monitoring information.

2. The method according to claim 1, wherein the frequency evaluation is implemented as a Fourier transform by which the received signal is decomposed into its frequency components in order to carry out the evaluation of the transformer parameter on the basis of the frequency components.

3. The method according to claim 1, wherein the monitoring component is structurally separate from the transformer and the processing system.

4. The method according to claim 1, wherein the signal is generated in the form of an electromagnetic field by the transformer during operation, the monitoring component being arranged at least spatially on the transformer at a distance from the transformer within reception range of the signal.

5. The method according to claim 1, wherein the signal is implemented as a low frequency signal.

6. The method according to claim 1, wherein the following is carried out to evaluate the at least one transformer parameter:
receiving the output monitoring information by the processing system,
performing a process of the received monitoring information by an evaluation element to use a result of the processing as information about the transformer parameter.

7. The method according to claim 6, wherein the evaluation elements has at least one neural network to perform the process in accordance with machine learning on the basis of a learned information of the evaluation elements.

8. The method according to claim 6, wherein the transformer parameter is implemented as an electrical parameter of the transformer, in order to perform the process at least for measuring current at the transformer for detecting a load profile of the transformer.

9. The method according to claim 6, wherein the following is carried out at least before or during or after the output:
detecting a time information about a time of receiving the signal by the monitoring component,
associating the time information with the monitoring information to output the monitoring information with the associated time information,
performing the process based on the time information).

10. The method according to claim 1, wherein the frequency evaluation is carried out for frequencies at least in the range from 10 Hz to 100 Hz in order to carry out the evaluation of the transformer parameter likewise on the basis of specific frequency components in this range.

11. The method according to claim 1, wherein at least the carrying out of the frequency evaluation or the evaluation of the transformer parameter are carried out in real time.

12. The method according to claim 1, wherein a state of the transformer is monitored during operation.

13. The method according to claim 1, wherein the network is at least partially implemented as the internet.

14. A monitoring component for networked monitoring of at least one transformer, comprising:
a receiving component for receiving an electromagnetic signal at the active transformer, wherein the signal is specific to at least one transformer parameter of the transformer,
an evaluation component for carrying out a frequency evaluation on the basis of the received signal,
an output component for outputting monitoring information about a result of the frequency evaluation to a network for transmission to a processing system for evaluation of the transformer parameter based on the monitoring information.

15. A monitoring component according to claim 14, wherein the receiving component has a receiving antenna which is configured to receive the signal as a low frequency signal.

16. A system for networked monitoring of at least one transformer, comprising:
a monitoring component according to claim 14,
the processing system for evaluating the transformer parameter based on the monitoring information.

17. The system according to claim 16, wherein the monitoring component comprises a time component to provide time information about a time interval for the frequency evaluation or about a time of receiving the signal by the monitoring component.

18. The method according to claim 5, wherein the signal is in the frequency range from 40 Hz to 70 Hz, with a frequency of essentially 50 Hz or 60 Hz.

19. The method according to claim 9, wherein the processing is based on sorting the received monitoring information in time based on the associated time information.

20. The monitoring component according to claim 15, wherein the low frequency signal is in the range from 40 Hz to 70 Hz.
